(19) United States
(12) Patent Application Publication
(10) Pub. No.: US 2007/0215863 A1
(43) Pub. Date: Sep. 20, 2007

(54) Fabricating apparatus with doped organic semiconductors

(75) Inventors: Christian Leo Kloc, New Providence, NJ (US); Oleg Mitrofanov, New York, NY (US); Theo Max Siegrist, Livingston, NJ (US); John Magnus Wikberg, Tullinge (SE); David V. Lang, Madison, NJ (US)

Correspondence Address: HITT GAINES, PC;ALCATEL-LUCENT, PO BOX 832570, RICHARDSON, TX, 75083, US

(73) Assignees: Lucent Technologies Inc., Murray Hill, NJ (US); Columbia University, New York, NY (US)

(21) Appl. No.: 11/375,833

(22) Filed: Mar. 15, 2006

(51) Int. Cl. H01L 29/08; H01L 35/24; H01L 51/00

(52) U.S. Cl. 257/40

(57) ABSTRACT

A method includes forming a semiconducting region including polyaromatic molecules on a surface of a substrate. The method also includes forming over the region a substantially oxygen impermeable dielectric layer. The act of forming a semiconducting region includes exposing the molecules to oxygen while exposing the molecules to visible or ultraviolet light.

### STATEMENT REGARDING FEDERALLY SPONSORED RESEARCH OR DEVELOPMENT

The U.S. Government has a paid-up license in this invention and the right in limited circumstances to require the patent owner to license others on reasonable terms as provided for by the terms of contract No. DE-FG02-04ER46118 awarded by the Department of Energy.

### TECHNICAL FIELD OF THE INVENTION

The present invention is directed, in general, to organic semiconductors.

### BACKGROUND OF THE INVENTION

Organic semiconductors are the subject of intense research interest. Potential benefits of these materials include low-cost, wide area coverage, and use with flexible electronic devices. They have been employed in organic light-emitting diodes (oLEDs) and organic field-effect transistors (oFETs), and in circuits integrating multiple devices. Fabrication techniques such as ink-jet printing have helped reduce the cost of fabrication of these devices and integrated circuits using them.

### SUMMARY OF THE INVENTION

One embodiment is a method that includes forming a semiconducting region on a surface of a substrate. The region includes polyaromatic molecules. The method also includes forming a dielectric layer substantially impermeable to oxygen over the region. The act of forming a semiconducting region includes exposing the molecules to oxygen while exposing the molecules to visible or ultraviolet light.

Another embodiment is a method that includes forming a semiconducting region including polyaromatic molecules on a surface of a substrate. The act of forming the region includes exposing the molecules to oxygen while exposing the molecules to light, the light being able to produce molecular electronic excitations in the molecules. The method also includes then forming a capping layer that is substantially impermeable to oxygen over the region.

Another embodiment is an apparatus. The apparatus includes an electronic device having an organic semiconductor channel placed over a substrate. First and second electrodes contact the channel. The electronic device includes a capping material configured to substantially exclude light and oxygen from the channel. The channel includes polyaromatic organic molecules.

In some embodiments, a portion of the polyaromatic organic molecules includes oxygen.

In some embodiments, the channel has a p-type semiconducting behavior.

### BRIEF DESCRIPTION OF THE DRAWINGS

Various embodiments are understood from the following detailed description, when read with the accompanying figures. Various features may not be drawn to scale and may be arbitrarily increased or reduced in size for clarity of discussion. Reference is now made to the following descriptions taken in conjunction with the accompanying drawings, in which:

FIG. 1 presents a method for forming a semiconducting region and an impermeable layer;

FIGS. 2A through 2G illustrate examples of organic semiconducting molecules;

FIGS. 3A through 3F illustrate examples of organic semiconducting polymers;

FIGS. 4A and 4B illustrate a mechanism of forming an endoperoxide of an organic semiconducting molecule;

FIG. 5 illustrates an example apparatus; and

FIGS. 6A and 6B illustrate an example electronic device.

### DETAILED DESCRIPTION OF ILLUSTRATIVE EMBODIMENTS

Some polyaromatic semiconductors have been found to have relatively poor stability in the presence of oxygen. In some conditions, oxygen may react with an aromatic ring in a polyaromatic molecule, thereby altering the electronic properties of the molecule. While such instability may be regarded as undesirable in electronics applications requiring long-term stability, the mechanism may be exploited to provide doping of such semiconductors.

Some of the embodiments recognize the benefits of increasing the conductivity of a p-type semiconducting polyaromatic layer by exposure to oxygen and light. These embodiments stabilize the conductivity of the layer by subsequent exclusion of light and oxygen from the layer.

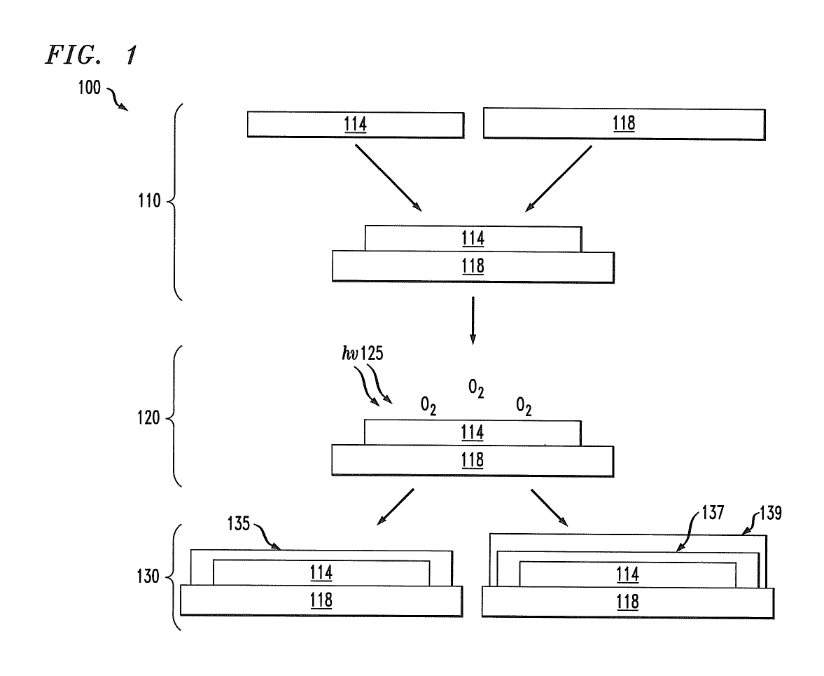

FIG. 1 illustrates a method 100. In a step 110, an organic semiconducting region 114 is conventionally formed. In some cases, the semiconducting region 114 may be formed on a substrate 118, while in other cases it may be formed separately and subsequently placed on the substrate 118. The semiconducting region 114 includes polyaromatic molecules. In one aspect the polyaromatic molecules form a single crystal. In another aspect, the polyaromatic molecules form a polycrystalline layer. A polycrystalline layer may include an amorphous portion.

Those skilled in the art will appreciate that polyaromatic molecules may be members of two broad classes. The first of these classes includes monodisperse compounds incorporating a plurality of aromatic or heteroaromatic units, where the units may be fused to each other and/or linked to each other in a way that maintains conjugation of π-bonds. Conjugated π-bonds provide for delocalization of electrons in the polyaromatic molecules. The second class includes polymers having the aforementioned polyaromatic characteristics. A subclass of polymers includes oligomers, e.g., polymer chains with less than about 10 repeating units. The polyaromatic molecules in these classes are typically characterized by having p-type semiconducting properties in the solid phase. Numerous such molecules are known in the art. For example, such molecules include acenes, thiophenes, di-anhydrides, di-imides, phthalocyanine salts, and derivatives of these classes of molecules.

Acenes are polyaromatic compounds having fused phenyl rings in a rectilinear arrangement, e.g., three or more such fused rings. A subclass of acenes includes those in which the aromatic rings are arranged in a linear fashion, as shown below. Among the linear acenes investigated for semiconducting applications are tetracene (n=2) and pentacene (n=3).

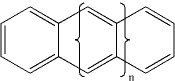

Thiophenes are molecules that have a five-member ring containing sulphur. Thiophenes having p-type semiconducting characteristics include those having one or more fused phenyl rings arranged in a linear fashion, with a terminal fused thiophene ring. A general structural representation of thiophenes having two terminal thiophene rings is shown below, for which n=0, 1, 2 . . . .

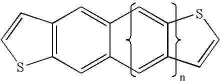

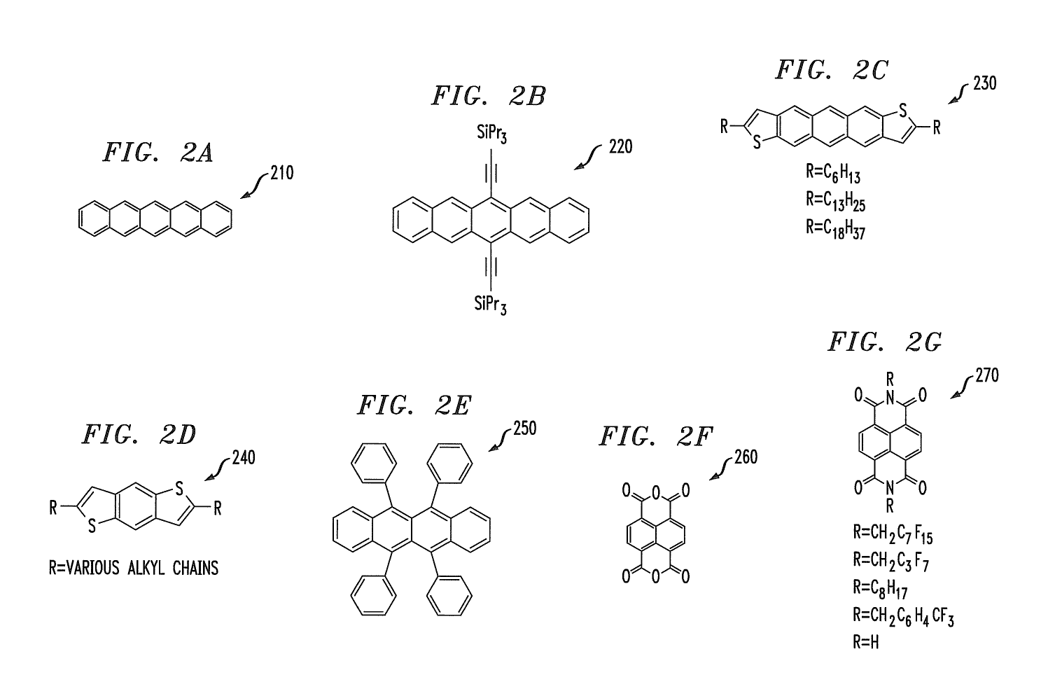

FIG. 2 shows examples of polyaromatic molecules with semiconducting properties. These examples include: pentacene 210 and processable derivatives thereof such as 6,13-bis (triisopropylsilylethynyl) pentacene (TIPS) 220; processable derivatives of anthradithiophene 230 and benzodithiophene 240; 5,6,11,12-tetraphenylnaphthacene (rubrene) 250 and processable derivatives thereof; naphthalene-1,4,5,8-tetracarboxyl di-anhydride 260; and derivatives 270 of N-substituted naphthalene-1,4,5,8-tetracarboxylic di-imide.

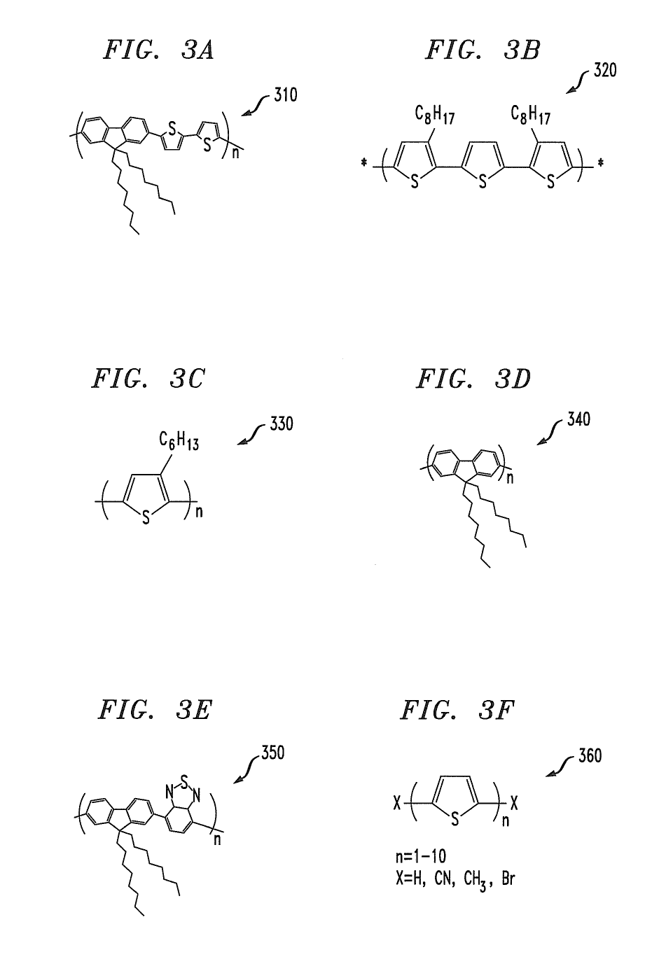

FIGS. 3A-3E show examples of polyaromatic polymers. The examples include: poly(9,9-dioctylfluorene-alt-bithiophene (F8T2) 310; poly (3,3′-dioctylterthiophene) (PTT8) 320; regioregular poly(3-hexylthiophene) (P3HT) 330; poly(9,9-dioctylfluorene) (F8) 340; and poly(9,9-dioctylfluorene-alt-benzothiadiazole) (F8BT) 350. Additionally, FIG. 3F illustrates the oligomeric polyaromatic molecule oligothiophene 360, and derivatives thereof. Those skilled in the pertinent art will appreciate that the above examples of polyaromatic molecules are not exhaustive of such molecules.

Semiconducting organic molecules do not typically have a significant population of electrons and holes in equilibrium in the absence of an applied electric field. Hence, the conductivity of such molecules is generally low relative to inorganic semiconductors. For example, while intrinsic silicon has a conductivity of about 1.5e-5 Ω⁻¹cm⁻¹, intrinsic pentacene 210 may have a conductivity of about 1.8e-8 Ω⁻¹cm⁻¹ and intrinsic rubrene 250 may have a conductivity of about 1e-9 Ω⁻¹cm⁻¹.

Moreover, the electrical properties of some organic semiconducting films may be unstable. In some cases, exposure of such films to oxygen and water vapor from the ambient causes changes in the conductivity in the films and mobility of charge carriers in the films. In some such cases, it is thought that exposure to oxygen results in changes to the semiconducting film by reacting with molecules in the film to create electron traps.

The electron traps may act as p-type dopants, providing for p-type semiconducting characteristics of the organic semiconducting film. Thus, such exposure may be advantageous if done in a controlled manner that results in stable semiconducting characteristics.

Such controlled doping of the polyaromatic molecules is provided in the method 100. In a step 120, the polyaromatic molecules are exposed to oxygen while exposing the molecules to visible or ultraviolet light 125. As described below, such exposure establishes an initial doping level of holes in the semiconducting region 114. In one aspect, the exposure may be done after a layer of polyaromatic molecules is formed. In another aspect, the exposure may be done simultaneously with the formation of the layer. In another aspect, the layer may be formed by alternating formation of a portion of the layer with exposure of the portion.

It is well known that oxygen molecules may exist in a ground energy state referred to as “triplet oxygen.” The oxygen is in a triplet state when one unpaired electron occupies each of the molecule's two degenerate antibonding π-orbitals and these two electrons form a state with total spin 1. The term “triplet” refers to the degeneracy of the energy states of the molecule, where the degeneracy is equal to unity plus twice the total electron spin.

Oxygen may also exist in a metastable singlet state, in which two spin-paired electrons occupy one antibonding π-orbital. Because the total electron spin is zero, the degeneracy is unity, and the molecule is referred to as “singlet.” The energy difference between triplet and singlet oxygen is about 0.98 eV (about 94 kJ/mol), corresponding to a transition in the near-infrared at about 1270 nm.

Triplet oxygen is generally prohibited by molecular orbital considerations from reacting with double bonds in an unsaturated organic molecule. The oxygen molecule typically must be excited to the singlet state, in which one oxygen atom may act as a Lewis acid while the other oxygen atom acts as a Lewis base. In this state, the oxygen molecule may react with a double bond.

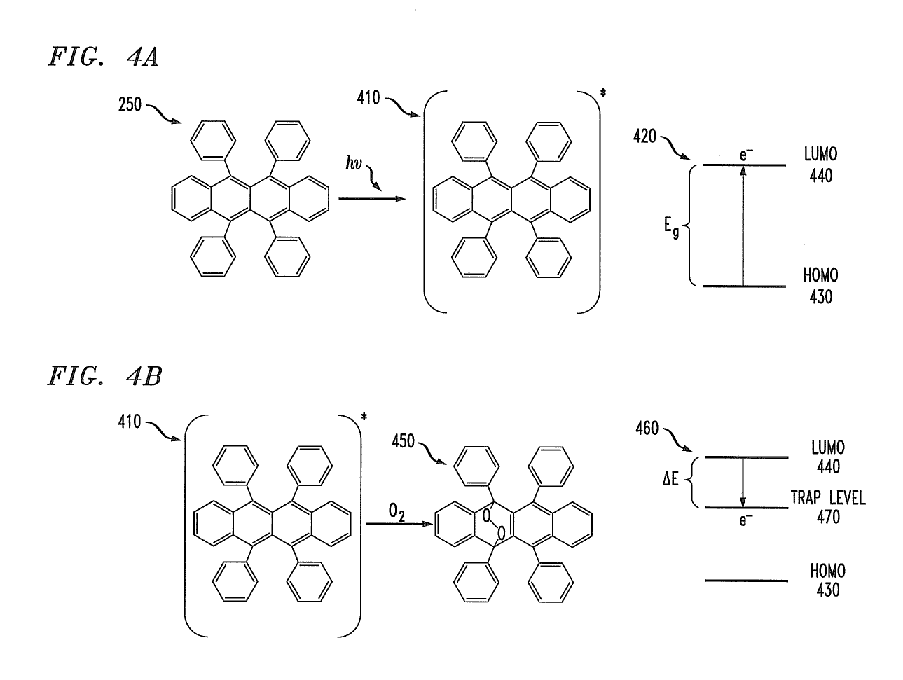

The oxygen molecule seems to be excitable to the singlet state through an interaction with a polyaromatic molecule in an exited molecular electronic state. FIG. 4 illustrates a model that is believed to illustrate one possible excitation pathway of the polyaromatic molecule, using rubrene 250 as an example. This model is presented without limitation, and does not preclude the possibility of other excitation pathways.

In FIG. 4A, a rubrene molecule 250 captures a photon of sufficient energy to excite an electron from a bonding molecular orbital (MO) with energy at or below a highest occupied molecular orbital (HOMO) to an antibonding MO with energy at or above a lowest unoccupied molecular orbital (LUMO). The absence of an electron in the bonding MO may be viewed as a “hole” in the bonding MO. The electron and hole may interact to form an excited electronic state of the molecule, or exciton. The excited molecule 410 is denoted with an asterisk.

Energy level diagram 420 illustrates the excitation of the electron from the HOMO 430 to the LUMO 440. The energy gap E_{g} represents the minimum photon energy required to excite the electron to an antibonding orbital. A photon with energy greater than E_{g} may excite an electron with energy below the level of the HOMO 430 to a state above the energy of the LUMO 440.

In FIG. 4B, an oxygen molecule in the ambient may interact with the excited molecule 410 to form a singlet oxygen molecule. The singlet oxygen may then react with a carbon atom in a polyaromatic molecule to form, e.g., an endoperoxide 450 or other oxygen-containing derivative of the polyaromatic molecule. In some cases, the rate of production of the derivative may increase as the temperature of the reactants is increased. In the following discussion, the oxygen-containing derivative is assumed for brevity to be the endoperoxide 450, recognizing that other oxygen-containing derivatives are possible.

Energy level diagram 460 illustrates the reduction of the energy of the excited electron from the LUMO 440 to a trap level 470 upon the reaction of the oxygen molecule with the excited molecule 410. Thus, the formation of the endoperoxide 450 has the effect of trapping an electron in a carbon-oxygen bond, leaving the hole in a bonding MO. The hole may then move from the endoperoxide 450 to a neighboring molecule in the semiconducting region 114 by well-known mechanisms such as electron hopping.

An endoperoxide of the polyaromatic molecule can therefore be viewed as a p-type dopant in the semiconducting region 114. A higher concentration of endoperoxide molecules results in a higher concentration of p-type dopant, and thus a higher conductivity of the semiconducting region 114.

In one aspect, in step 120 the oxygen molecules are provided by a standard atmosphere, e.g., about 20% molecular oxygen and 80% molecular nitrogen at about 101 kPa total pressure. Such exposure results in exposure to an oxygen partial pressure of approximately 20 kPa. In another aspect, the semiconducting region 114 is exposed to a partial pressure of oxygen exceeding that of a standard atmosphere. In another aspect, the semiconducting region 114 is exposed to a gaseous environment that substantially excludes all gases other than oxygen.

The light 125 that illuminates the semiconducting region 114 during exposure to oxygen may be visible or ultraviolet. The light provides the energy to the optical processes that result in transforming the polyaromatic molecules to the excited molecular state. The optical process may be a single or multiple photon process. Each optical process in a particular polyaromatic molecule will have a minimum energy at which the process proceeds. A multiple photon process will proceed at lower photon energy than a single photon process.

For example, in rubrene a single photon process may proceed for a photon having a minimum energy of about 2 eV, corresponding to the red portion of the visible spectrum. Thus, in some cases, the minimum energy of light used to illuminate rubrene should include light with energy about 2 eV or higher. In other cases, light with energy lower than 2 eV may provide a multiple photon process that creates an excited molecular state. Different polyaromatic molecules will generally have different characteristic energies associated with optical processes that produce an excited molecular electronic state. Thus, in general, the minimum energy of the light used may be chosen to correspond to the energy associated with an optical process of the polyaromatic molecule of interest.

Each polyaromatic molecule has a characteristic absorption spectrum associated therewith. The transmission of light through a layer of polyaromatic molecules may therefore be greater at some frequencies than at others. Thus, in some cases, light with energy greater than the minimum required may advantageously penetrate deeper into a layer comprising the polyaromatic molecules. However, if the energy exceeds a value sufficient to break molecular bonds, some molecules may be broken down or altered in an undesirable manner. Therefore, there is a high energy limit of the light 125, which may differ for different polyaromatic molecules. In one aspect, this high energy limit may be the photolysis threshold where the singlet oxygen is released by the endoperoxide. In another aspect, the high energy limit is in the far-ultraviolet, exceeding about 6 eV, or below about 200 nm wavelength.

The conductivity of the semiconducting region 114 may be increased by appropriate choice of the partial pressure of oxygen, the duration and intensity of exposure to light, and the wavelength of light. In some cases, the semiconducting region 114 may be heated above room temperature (about 25° C.) during exposure. Higher doping levels may be achieved more readily by exposure of the semiconducting region 114 during formation of a layer thereof, or in alternation with formation of multiple portions of a layer. In this manner, a doping level of 1e18 cm⁻³ or greater may be provided.

As an example, an intrinsic rubrene layer may be doped by exposure to light provided by fluorescent fixtures in a typical office environment. Such exposure, in the presence of atmospheric oxygen at about 100° C. for about 12 hours, may increase the conductivity of the rubrene layer by about 250%. Appropriate exposure conditions may differ when other polyaromatic molecules are used. The time of exposure may be reduced by use of a broad-spectrum, high-intensity source such as a xenon arc lamp while filtering to remove wavelengths below about 280 nm.

In a step 130, a blocking layer 135 substantially impermeable to oxygen is formed over the doped semiconducting region 114. Substantially impermeable means that the rate of oxygen diffusion through the layer is below a minimum rate that results in a significant change of semiconducting characteristics of the semiconducting region 114 over the operational lifetime of a device employing the semiconducting region 114. By substantially excluding oxygen from the semiconducting region 114, stability of the doping level of the semiconducting region 114 may be improved over the case in which the semiconducting region 114 remains exposed to the ambient atmosphere. Loss of doping species after step 120 may be reduced by, e.g., minimizing exposure of the doped semiconducting region 114 to light prior to the step 130, and/or minimizing the time between the step 120 and the step 130.

The thickness of the blocking layer 135 may depend on the material used to form the blocking layer 135. It will be readily apparent that a blocking layer 135 formed of a material with a higher diffusion coefficient of oxygen will be thicker than a blocking layer 135 formed of a material with a lower diffusion coefficient to maintain the same lifetime of the device.

In one aspect, the blocking layer 135 may be a dielectric film. Such a dielectric film may be deposited in any conventional manner appropriate to the dielectric layer that does not substantially alter the properties of the semiconducting region 114. In another aspect, the blocking layer 135 may be a polymer. One such polymer is parylene, in which oxygen may have a permeability of about 6e-8 μm²s⁻¹Pa⁻¹ at about 23° C. Parylene may be deposited from the vapor phase in a highly conformal, pinhole-free form. In one aspect, a thickness of 2 μm of parylene is a suitable oxygen barrier. In some cases, the blocking layer 135 may be used as a gate dielectric of a FET formed using the semiconducting region 114 as a channel.

As described previously, exposure to light may undesirably cause the endoperoxide reaction to reverse, liberating oxygen and consuming a hole. In an embodiment, the blocking layer 135 is also substantially opaque to visible and/or ultraviolet light. By substantially opaque, it is meant that the blocking layer 135 absorbs or reflects substantially all light in the wavelength range of interest. In one aspect, the blocked light has a short enough wavelength to produce molecular electronic excitations in some of the polyaromatic molecules, and the blocking layer 135 substantially prevents the blocked light from illuminating the semiconducting region 114.

In some cases, the blocking layer 135 includes a plurality of sublayers, at least one sublayer 137 being optimized for oxygen impermeability, and at least one sublayer 139 being optimized for exclusion of visible and/or ultraviolet light. As an example, the sublayer 137 may be parylene, and the sublayer 139 may be an opaque layer placed over the semiconducting region 114 after forming an electronic device therewith. In another example, the sublayer 139 is a gate electrode layer of an FET. In another example, the blocking layer 135 may be a portion of a package containing the semiconducting region 114. In another example, the blocking layer 135 is a dielectric mirror, comprising multiple dielectric layers designed to result in reflection of a substantial portion of the light. In another example, the blocking layer 135 may be a composite layer, including a component to exclude oxygen and a component to block the light.

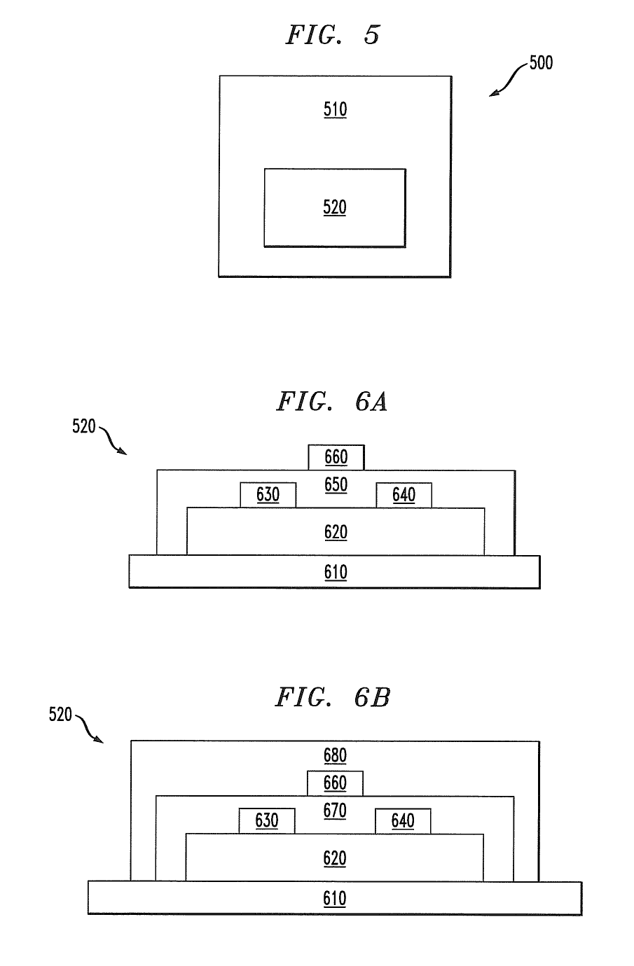

Another embodiment is an apparatus. FIG. 5 illustrates an example apparatus 510. The apparatus 510 includes an electronic device 520 that in turn includes the semiconducting region 114 that includes polyaromatic molecules, e.g., one or more of the above-described species of polyaromatic molecules. The semiconducting region 114 may form a channel of the electronic device 520. The electronic device 520 may be, e.g., a resistor, a FET, or an LED. First and second electrodes are placed in contact with the semiconducting region 114, and a structure is provided to substantially exclude visible and/or ultraviolet light and oxygen from the semiconducting region 114. The channel includes polyaromatic organic molecules, and a portion of the polyaromatic organic molecules includes oxygen such that the channel has a p-type semiconducting behavior.

FIG. 6A illustrates a FET 600. A substrate 610 is provided on which a semiconducting region 620 is formed as provided by the method 100. The semiconducting region 620 may have a p-type doping level of at least about 1e16 cm⁻³. Source and drain electrodes 630, 640 are formed conventionally and placed in contact with the semiconducting region 620. While a top-gate FET is shown, other electrode configurations are possible and contemplated.

A blocking layer 650 is formed over the semiconducting region 620. The blocking layer 650 substantially excludes oxygen and ultraviolet and visible light from the semiconducting region 620. A gate electrode 660 is placed over the excluding layer to control the conductivity of the semiconducting region 620.

FIG. 6B illustrates a FET 520 formed using multiple sublayers 670, 680 to exclude oxygen and light from the semiconducting region 620. In one aspect, the sublayer 670 may be a dielectric that is suitable as a gate dielectric and substantially excludes oxygen from the semiconducting region 620. In another aspect, the sublayer 680 substantially blocks light capable of producing molecular excitations of polyaromatic molecules of semiconducting region 520.

The electrodes 630, 640, 660 may be formed by conventional techniques methods such as shadow mask and physical vapor deposition (PVD) of metal, or by photolithographic processes. Electrical connections are made to the electrodes by suitable manner to result in a functioning apparatus 510.

Although the present invention has been described in detail, those skilled in the pertinent art should understand that they could make various changes, substitutions and alterations herein without departing from the spirit and scope of the invention in its broadest form.

What is claimed is:

1. A method, comprising:
forming a semiconducting region including polyaromatic molecules on a surface of a substrate; and
then, forming a substantially oxygen impermeable dielectric layer over the region; and
wherein the act of forming a semiconducting region includes exposing the molecules to oxygen while exposing the molecules to visible or ultraviolet light.

2. The method of claim 1, wherein the layer is substantially opaque to the light.

3. The method of claim 1, wherein the layer substantially prevents the light from illuminating the region, wherein the light has a short enough wavelength to produce molecular electronic excitations in some of the polyaromatic molecules.

4. The method of claim 1, wherein the region is a layer including the molecules.

5. The method of claim 1, wherein the molecules are selected from the group consisting of acenes and thiophenes.

6. The method of claim 1, wherein the molecules are rubrene, a substituted rubrene, pentacene, or a substituted pentacene.

7. The method of claim 1, wherein the light has a short enough wavelength to produce molecular electronic excitations in some of the polyaromatic molecules.

8. A method, comprising:
forming a semiconducting region including polyaromatic molecules on a surface of a substrate; and
then, forming a substantially oxygen impermeable capping layer over the region; and
wherein the act of forming a semiconducting region includes exposing the molecules to oxygen while exposing the molecules to light, the light being able to produce molecular electronic excitations in some of the molecules.

9. The method of claim 8, wherein the layer stops visible and ultraviolet light from illuminating the region.

10. The method of claim 8, wherein the layer stops light from illuminating the region, wherein the stopped light has a short enough wavelength to produce molecular electronic excitations in some of the polyaromatic molecules.

11. The method of claim 8, wherein the region is a polycrystalline layer.

12. The method of claim 8, wherein the molecules are selected from the group consisting of acenes and thiophenes.

13. The method of claim 8, wherein the region functions as a p-type semiconductor.

14. An apparatus, comprising:
an electronic device having:
an organic semiconductor channel placed over a substrate;
first and second electrodes in contact with the channel; and
a capping material configured to substantially exclude light and oxygen from the channel,
wherein the channel comprises polyaromatic organic molecules, a portion of the polyaromatic organic molecules including oxygen to produce p-type semiconducting behavior.

15. The apparatus of claim 14, wherein the capping material forms a layer over the channel, the layer being substantially opaque to light with a shorter wavelength than a maximum wavelength capable of inducing an exited electronic state in one of the polyaromatic molecules.

16. The apparatus of claim 14, wherein the channel functions as a p-type semiconductor.

17. The apparatus of claim 14, wherein said layer includes an endoperoxide.

18. The apparatus of claim 14, wherein the molecules are selected from the group consisting of acenes and thiophenes.

19. The apparatus of claim 14, wherein the molecules are selected from the group consisting of rubrene, substituted rubrene, pentacene, and substituted pentacene.

20. The apparatus of claim 14, wherein the channel has a p-type doping of 10¹⁶ cm⁻³ or greater.
